(19) United States
(12) Patent Application Publication
(10) Pub. No.: US 2023/0395758 A1
(43) Pub. Date: Dec. 7, 2023

(54) DISPLAY DEVICE

(71) Applicant: Japan Display Inc., Tokyo (JP)

(72) Inventor: Kazuyuki YAMADA, Tokyo (JP)

(73) Assignee: Japan Display Inc., Tokyo (JP)

(21) Appl. No.: 18/201,209

(22) Filed: May 24, 2023

(30) Foreign Application Priority Data
Jun. 7, 2022 (JP) 2022-092203

(51) Int. Cl. H01L 33/46; H01L 33/62; H01L 33/58; H01L 25/075

(52) U.S. Cl. CPC H01L 33/465; H01L 25/0753; H01L 33/58; H01L 33/62

(57) ABSTRACT

A display device includes a first substrate, a light-emitting element on the first substrate, a second substrate opposed to the first substrate, a first protruding structure surrounding the light-emitting element on a surface of the second substrate opposed to the first substrate, and a light-shielding film overlapping the first protruding structure between the first substrate and the second substrate, wherein a supplementary angle of an inclination angle of a side surface of the first protruding structure is 30 degrees or more and 90 degrees or less. In addition, the display device further includes a reflective film on the side surface of the first protruding structure. Furthermore, the light-shielding film is located between the first protruding structure and the second substrate. Besides, a surface of the first protruding structure on a side of the second substrate is smaller than the light-shielding film.

### CROSS-REFERENCE TO RELATED APPLICATION

This application claims the benefit of priority to Japanese Patent Application No. 2022-092203 filed on Jun. 7, 2022, the entire contents of which are incorporated herein by reference.

### FIELD

An embodiment of the present invention relates to a display device, particularly, a display device including a light-emitting diode (LED).

### BACKGROUND

In recent years, a so-called micro LED display in which a minute micro LED is arranged in a pixel has been developed as a next-generation display. The micro LED is a self-luminous element similar to an OLED (Organic Light Emitting Diode), but unlike the OLED, the micro LED display is more reliable than the OLED display because the micro LED is composed of a stable inorganic compound containing gallium (Ga) or indium (In) and the like. Further, the micro LED has high luminous efficiency and can realize high brightness. Therefore, the micro LED display is expected as a next-generation display with high reliability, high brightness, and high contrast.

Among micro LED displays, there is a known method for improving a front brightness of a display by using a light-shielding layer that emits light from a light-emitting element in a substrate on which the light-emitting element is mounted. (For example, see WO 2021/033775).

However, simply adjusting the front brightness of the display may not suppress the internal reflection of the light emitted from an upper surface and a side surface of the light-emitting element, and a problem of reduction in contrast (mainly a decrease in the display of black color) may occur. In addition, in the micro LED display, since a transistor or an IC chip (integrated circuit chip) using a highly reflective metal material or the like may be arranged around the light-emitting element, the light emitted from the light-emitting element may be reflected at interfaces of the transistor and the IC chip, and the reduction in contrast may occur.

### SUMMARY

A display device according to an embodiment of the present invention includes a first substrate, a light-emitting element on the first substrate, a second substrate opposed to the first substrate, a first structure surrounding a light-emitting element on a surface of the second substrate opposed to the first substrate, and a light-shielding film overlapping the first structure between the first substrate and the second substrate, wherein a supplementary angle of an inclination angle of a side surface of the first structure is 30 degrees or more and less than 90 degrees.

### BRIEF DESCRIPTION OF DRAWINGS

FIG. 1 is a schematic plan view of a display device according to an embodiment of the present invention.

FIG. 2 is a schematic plan view of a display device according to an embodiment of the present invention.

FIG. 3 is a schematic cross-sectional view of a display device according to an embodiment of the present invention.

FIG. 4 is a schematic cross-sectional view of a manufacturing method of a display device according to an embodiment of the present invention.

FIG. 5 is a schematic cross-sectional view of a display device according to an embodiment of the present invention.

FIG. 6 is a schematic cross-sectional view of a display device according to an embodiment of the present invention.

FIG. 7 is a schematic plan view of a display device according to an embodiment of the present invention.

FIG. 8 is a schematic cross-sectional view of a display device according to an embodiment of the present invention.

FIG. 9 is a schematic cross-sectional view of a display device according to an embodiment of the present invention.

FIG. 10 is a schematic plan view of a display device according to an embodiment of the present invention.

FIG. 11 is a schematic cross-sectional view of a display device according to an embodiment of the present invention.

FIG. 12 is a schematic cross-sectional view of a display device according to an embodiment of the present invention.

FIG. 13 is a schematic cross-sectional view of a display device according to an embodiment of the present invention.

FIG. 14 is a schematic cross-sectional view of a display device according to an embodiment of the present invention.

### DESCRIPTION OF EMBODIMENTS

Hereinafter, each embodiment according to the present invention will be described with reference to the drawings. Each of the embodiments is merely an example, and those that can be easily conceived by a person skilled in the art by making appropriate changes while keeping the gist of the invention are naturally included in the scope of the present invention. In addition, in order to make the description clearer, the drawings may schematically show the width, thickness, shape, and the like of each part in comparison with an actual embodiment. However, the illustrated shapes are merely examples, and do not limit the interpretation of the present invention.

In the present specification, the phrase “α includes A, B, or C,” “α includes any of A, B, and C,” “α includes one selected from a group consisting of A, B, and C,” and the like does not exclude the case where α includes a plurality of combinations of A to C unless otherwise indicated. Furthermore, these expressions do not exclude the case where α includes other elements.

In the present specification, although the phrases “on” or “above” or “under” or “below” are used for convenience of explanation, in principle, a substrate on which a structure is formed is used as a reference, and a direction from the substrate to the structure is defined as “on” or “above”. Conversely, a direction from the structure to the substrate is defined as “under” or “below”. Therefore, in the expression “light-emitting element on a substrate”, a substrate side surface of the light-emitting element is a lower surface, and the other side surface thereof is an upper surface. In addition, in the expression “light-emitting element on a substrate”, only the vertical relationship between the substrate and the light-emitting element is described, and another member may be arranged between the substrate and the light-emitting element. Furthermore, the phrases “on” or “above” or “under” or “below” refer to the order in which a plurality of layers is stacked, and may not be in a positional relationship overlapping in a plan view.

In the present specification, the term “display device” broadly includes a device that displays an image using a light-emitting element, and may include not only a display panel and a display module but also a device to which other optical members (for example, a polarizing member, a backlight, a touch panel, or the like) are attached.

The following embodiments can be combined with each other as long as no technical contradiction is caused.

### FIRST EMBODIMENT

### 1. Overall Configuration

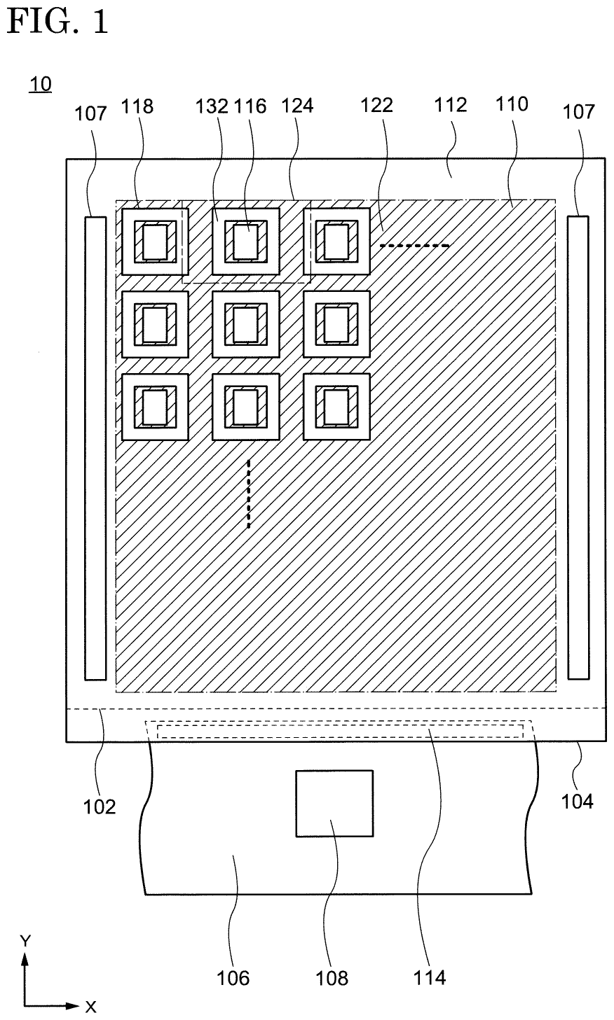

The present embodiment shows a configuration of a display device 10 according to an embodiment. FIG. 1 is a schematic plan view of a display device according to the present embodiment.

As shown in FIG. 1, the display device 10 includes a first substrate 102, a second substrate 104, a flexible printed circuit board 106, and an IC chip 108. The first substrate 102 and the second substrate 104 are arranged to face each other. A display area 110 is arranged in an area where the first substrate 102 and the second substrate 104 face each other. A plurality of pixels 118 is arranged in the display area 110. The display device 10 further includes a peripheral area 112 and a terminal area 114 outside the display area 110.

A first structure 132 is arranged in the display area 110. The first structure 132 is arranged over the entire display area 110. The first structure 132 has an opening pattern in which a light-emitting element 116 is exposed. The opening pattern of the first structure 132 is arranged corresponding to the pixel 118. In other words, the light-emitting element 116 is arranged to be surrounded by the first structure 132. In FIG. 1, although an example is shown in which one light-emitting element 116 is arranged in one opening pattern of the first structure 132, a plurality of light-emitting elements 116 may be arranged in one opening pattern in the case where the plurality of light-emitting elements 116 is arranged in the pixel 118. For example, three light-emitting elements 116 may be arranged in one opening pattern of the first structure 132. As described above, an area where the first structure 132 surrounds the light-emitting element 116 can be treated as one pixel 118.

In addition, a light-shielding film 122 is arranged in the display area 110. The light-shielding film 122 is arranged so as to overlap the first structure 132 in a plan view and so as not to block the opening pattern of the first structure 132. In other words, the light-shielding film 122 is arranged so as to surround the light-emitting element 116 in a plan view. As shown in FIG. 1, the light-shielding film 122 is arranged so as to cover between the adjacent pixels 118 arranged in the display area 110. Arranging such a light-shielding film 122 in the display area 110 makes it possible to prevent light leakage between pixels. Although FIG. 1 shows an example in which the light-shielding film 122 is arranged in the display area 110, the light-shielding film 122 may extend to the peripheral area 112.

A driver circuit 107 for controlling the light emission state of the light-emitting element 116 arranged in each pixel 118 may be arranged in the peripheral area 112. In addition, in the first substrate 102, the terminal area 114 is arranged at one end of the peripheral area 112. A plurality of terminals is arranged in the terminal area 114. The flexible printed circuit board 106 is attached to the terminal area 114 and is electrically connected to the plurality of terminals. The IC chip 108 is mounted on the flexible printed circuit board 106. The IC chip 108 outputs a video signal. The video signal output from the IC chip 108 is transmitted to the driver circuit 107 arranged in the first substrate 102 via the flexible printed circuit board 106.

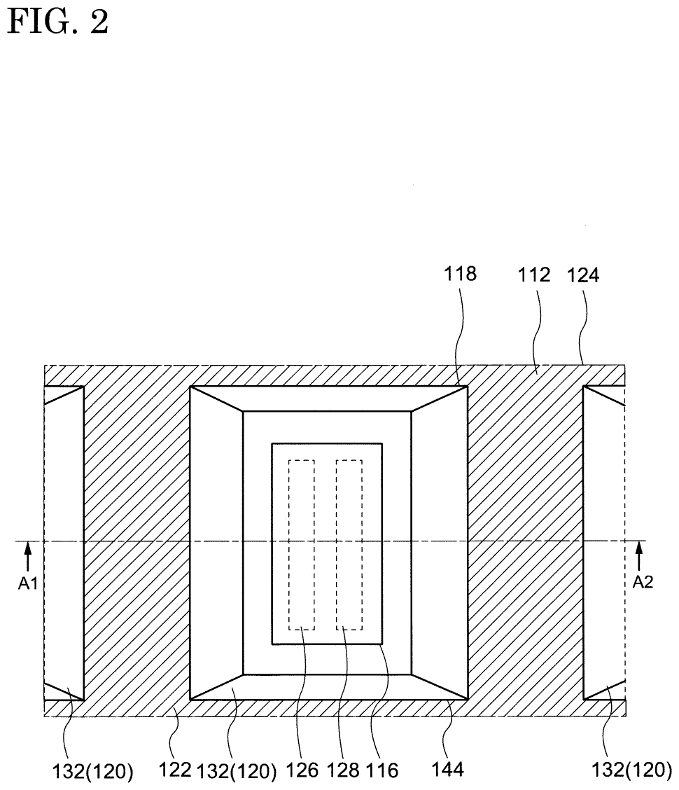

An enlarged view of an area 124 shown in FIG. 1 is shown in FIG. 2. FIG. 2 shows a plan view of the area 124, specifically a plan view of the pixel 118. The light-shielding film 122 has an opening 144. The opening 144 of the light-shielding film 122 is arranged so as to overlap the opening pattern of the first structure 132 described above. The light-emitting element 116 is arranged in an area inside the opening 144. Since the light-shielding film 122 has a function of blocking the light emitted from the light-emitting element 116, the area inside the opening 144 can be regarded as the pixel 118. FIG. 2 shows that in addition to the light-emitting element 116, part of an area of the first structure 132 is exposed at the opening 144. The part of the area is an area where a reflective film 120 is arranged along a side surface of the first structure 132. The pixel 118 includes the light-emitting element 116, a first conductive layer 126, a second conductive layer 128, and a portion of the first structure 132 (and the reflective film 120). The pixel 118 includes part of the first structure 132 in a plan view, and this part corresponds to a side surface 140 of the first structure 132 described later. The side surface 140 of the first structure 132 is arranged to surround the light-emitting element 116, the first conductive layer 126, and the second conductive layer 128. The light-emitting element 116 is arranged on the first conductive layer 126 and the second conductive layer 128. Although FIG. 2 shows an example in which one light-emitting element 116 is arranged in one pixel 118, the present invention is not limited to this example, and a plurality of light-emitting elements 116 may be arranged in one pixel 118.

### 2. Cross-Sectional Structure

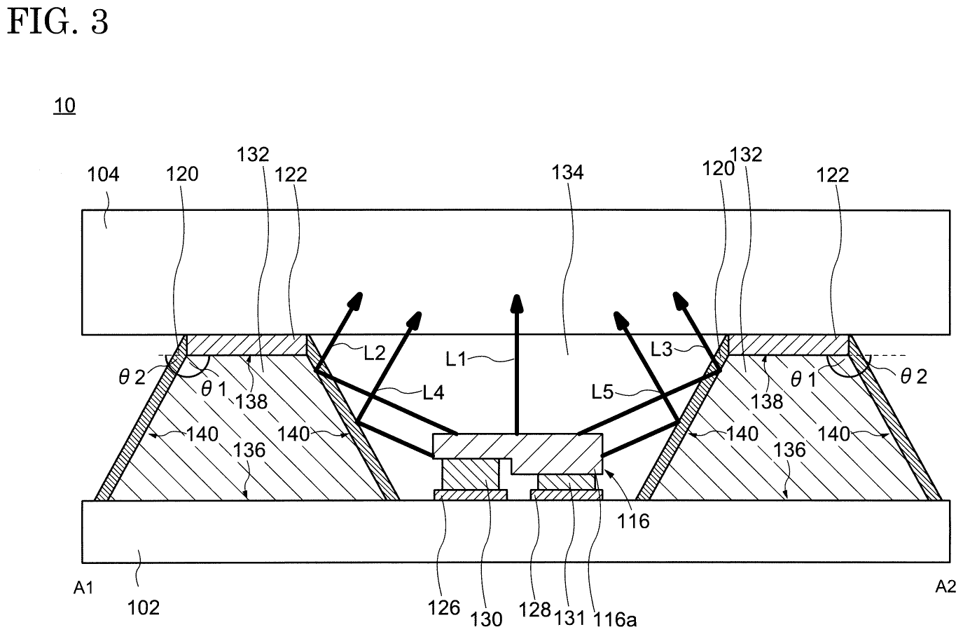

FIG. 3 shows a schematic cross-sectional view along a line A1-A2 shown in FIG. 2. As shown in FIG. 3, the light-emitting element 116 is arranged on the first substrate 102, and the first structure 132 is arranged so as to surround the light-emitting element 116 on the surface of the second substrate 104 facing the first substrate. In addition, the second substrate 104 is arranged facing the first substrate 102.

The light-emitting element 116 and the first structure 132 are arranged between the first substrate 102 and the second substrate 104. The first structure 132 has a constant height. In addition, the first structure 132 has a structure higher than an upper end of the light-emitting element 116. Therefore, since the first structure 132 is interposed between the first substrate 102 and the second substrate 104, a distance between the first substrate 102 and the second substrate 104 can be kept constant, and the light-emitting element 116 can be prevented from directly contacting the second substrate 104. As a result, as shown in FIG. 3, it is possible to form a space surrounding the light-emitting element 116. This space is a space in which the light-emitting element 116 is stored, and is referred to as a containment portion 134 in the present embodiment.

As shown in FIG. 3, the containment portion 134 is arranged between the first structure 132 and between the first substrate 102 and the second substrate 104 in a cross-sectional view. The containment portion 134 may be filled with a gas or a transparent resin material. For example, a mixed gas such as air, an inert gas, a nitrogen gas, or the like can be used as the gas. An acrylic resin, an epoxy resin, or the like can be used as the transparent resin material. In this case, it is preferable that the gas or the resin material filled in the containment portion 134 has a refractive index equivalent to a refractive index of the second substrate 104. In the case where the refractive index of the filling material is close to the refractive index of the second substrate 104, reflection at an interface between the second substrate 104 and the filling material can be suppressed, and light emitted from the light-emitting element 116 can be efficiently extracted from the display device 10. In addition, in the case where a resin or the like is used for the filling material, the entire second substrate 104 can be coated with the resin, and the containment portion 134 can be filled with the filling material. In addition, it is also possible to discharge the resin into the containment portion 134 and fill the containment portion 134 with the filling material.

As shown in FIG. 3, the first structure 132 has a first surface 138, which is a surface opposite the second surface 136, and has the side surface 140 between the second surface 136 and the first surface 138. The area of the first surface 138 is smaller than the area of the second surface 136, so that the side surface 140 is inclined and connected to the first surface 138 and the second surface 136. As shown in FIG. 3, the first structure 132 is trapezoidal in a cross-sectional view. In this case, assuming that an inclination angle of the side surface 140 with respect to the first surface 138 is θ1, a supplementary angle with respect to the inclination angle θ1 is θ2. For example, the supplementary angle θ2 of the inclination angle θ1 of the side surface 140 with respect to the first surface 138 is 30 degrees or more and less than 90 degrees. In addition, the inclination angle θ1 and the supplementary angle θ2 may be perpendicular to the first surface 138. Furthermore, a height of the first structure 132, that is, a distance from the first surface 138 to the second surface 136 is, for example, 5 μm or more and 50 μm or less. In the case where the light-shielding film 122 is arranged between the first structure 132 and the second substrate 104, the height of the first structure 132 may be a height combined with a thickness of the light-shielding film 122, that is, a distance between the first substrate 102 and the second substrate 104.

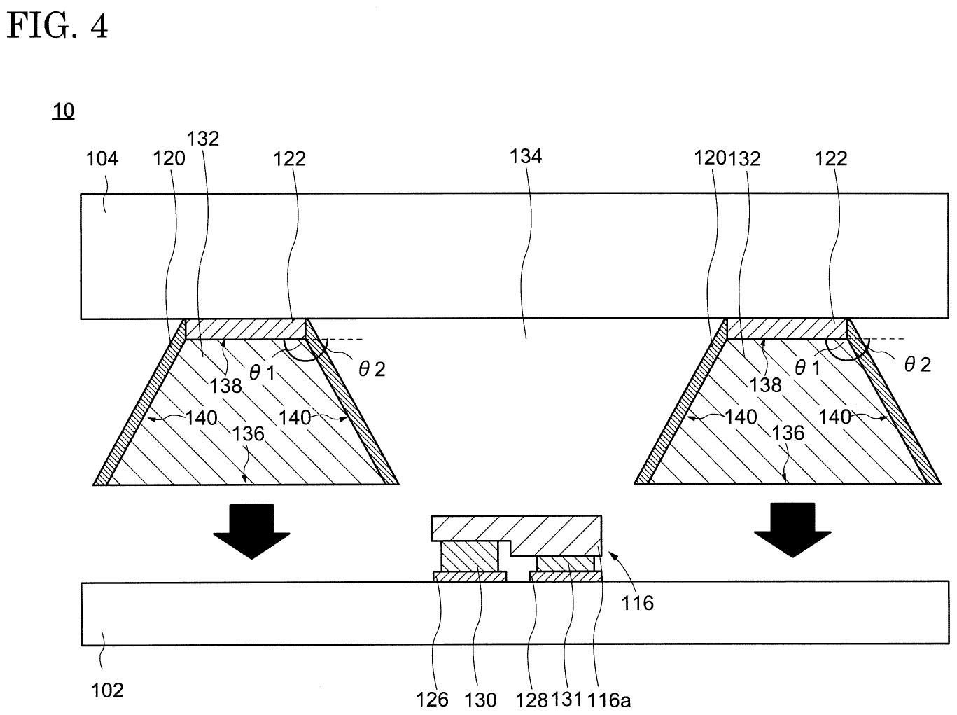

The first structure 132 is arranged in the second substrate 104. Since the first structure 132 is arranged in the second substrate 104, the display device 10 is manufactured through a bonding process as shown in FIG. 4. As shown in FIG. 4, when a surface of the first structure 132 facing the first substrate 102 is defined as the second surface 136, the second substrate 104 and the first substrate 102 are bonded such that the second surface 136 of the first structure 132 is in contact with the first substrate 102. A seal, a glass frit, an ultraviolet-curable filling resin, or the like can be used for bonding. In addition, the second surface 136 of the first structure 132 and the first substrate 102 may be bonded together at the time of bonding. The second surface of the first structure 132 and the first substrate 102 may be bonded by arranging an adhesive layer such as the ultraviolet curable-filling resin between the second surface 136 of the first structure 132 and the first substrate 102.

A material having a refractive index different from that of the filling material of the containment portion 134 is used as a material used for the first structure 132. For example, in the case where the filling material of the containment portion 134 is air, a resin having a refractive index of about 1.5 can be used. Making the refractive index of the filling material and the reflective index of the first structure 132 different and giving the side surface 140 an inclination angle as described above makes the side surface 140 (the interface between the first structure 132 and the filling material) a reflective surface, and the light emitted from the light-emitting element 116 is reflected toward the second substrate 104 to be outgoing light.

A reflective surface may be formed on the first structure 132 by arranging the reflective film 120 on the side surface 140. The reflective film 120 is arranged on the side surface 140 of the first structure 132. The reflective film 120 may be arranged so as to cover at least part of the side surface 140, and more preferably, may be arranged so as to cover the first surface 138 side or the second surface 136 side of the side surface 140. A material having a high reflectance of the light emitted from the light-emitting element 116 can be used for the reflective film 120, such as aluminum. Arranging the reflective film 120 makes it possible to reflect the light emitted from the light-emitting element 116 toward the second substrate 104 to be outgoing light.

The light-shielding film 122 is arranged to overlap the first surface 138 of the first structure 132. The light-shielding film 122 is arranged between the first structure 132 and the second substrate 104. As shown in FIG. 3, the light-shielding film 122 is arranged between the first surface 138 and the second substrate 104 located on the second substrate 104 side of the first structure 132. The light-shielding film 122 is smaller than the second surface 136 of the first structure 132 located on the first substrate 102 side. As shown in FIG. 3, in a cross-sectional view, since a width of the light-shielding film 122 has approximately the same size as a width of the first surface 138 of the first structure 132, the width of the light-shielding film 122 is smaller than the width of the second surface 136 that is larger than the width of the first surface 138. In a cross-sectional view, the light-shielding film 122 may be smaller than the area of the second surface 136 of the first structure 132.

For example, a light-emitting diode (LED) is used as the light-emitting element 116. For example, a red light-emitting diode, a green light-emitting diode, a blue light-emitting diode, or an ultraviolet light-emitting diode can be used as the light-emitting diode. In addition, the light-emitting diode includes a tiny light-emitting diode called miniature LED or micro LED.

In an embodiment of the present invention, the term “micro LED” refers to an LED having a chip size of several micrometers or more and 100 μm or less, and the term “miniature LED” refers to an LED having a chip size of 100 μm or more. An embodiment of the present invention can use any sized LED, and can be appropriately used depending on the application and form of the light-emitting device.

In the case where the light-emitting element 116 is a light-emitting diode, it has a p-side electrode and an n-side electrode. The n-side electrode is connected to the first conductive layer 126 by a first bump 130, and the p-side electrode is connected to the second conductive layer 128 by a second bump 131.

The first bump 130 and the second bump 131 are used for the electrical connection between the light-emitting element 116 and the first conductive layer 126 and the second conductive layer 128. FIG. 3 shows a configuration in which the light-emitting element 116 is provided in a flip-chip type LED chip, the first bump 130 is used for connection between the n-side electrode and the first conductive layer 126, and the second bump 131 is used for connection between the p-side electrode and the second conductive layer 128. In the flip-chip type LED chip, although the n-side electrode and the p-side electrode have different heights, the LED chip can be mounted horizontally by making the height of the first bump 130 higher than that of the second bump 131. The first bump 130 and the second bump 131 may be formed by plating, sputtering, vapor deposition, printing, or the like. For example, gold may be used for the material of the first bump 130 and the second bump 131, but is not limited to this.

The first conductive layer 126 and the second conductive layer 128 are electrically connected to a transistor (not shown) arranged in the first substrate 102. For example, the transistor is electrically connected to the driver circuit 107, and the light-emitting element 116 controls the light emission state. For example, examples of the material used for the first conductive layer 126 and the second conductive layer 128 include aluminum and silver.

A flexible substrate such as a polyimide substrate, an acryl substrate, a siloxane substrate, or a fluororesin substrate can be used as the first substrate 102 on which the light-emitting element 116 is mounted. In order to improve the heat resistance of the first substrate 102, impurities may be introduced into the flexible substrate. In the case where the first substrate 102 does not need to have flexibility, for example, a rigid substrate such as a glass substrate, a quartz substrate, or a sapphire substrate may be used as the first substrate 102. Although not shown in detail, the first substrate 102 may be a so-called circuit substrate in which a circuit for driving the light-emitting element 116 is formed. In addition, a structure from the first substrate 102 to the light-emitting element 116, excluding the first structure 132, the reflective film 120, the light-shielding film 122, and the second substrate 104 of the display device 10, may be referred to as an array substrate.

In this case, the progress of the light emitted from the light-emitting element 116 will be described with reference to FIG. 3.

The light-emitting element 116 emits light in all directions. Of the light emitted from the light-emitting element 116, the light emitted in the oblique direction and transverse direction is reflected toward the second substrate 104 by the reflective surface of the first structure 132 and changes its traveling direction. The reflective surface of the first structure 132 may change the traveling direction of the light emitted from the light-emitting element 116 in the oblique direction and transverse direction to the direction of the second substrate 104. For example, as shown in FIG. 3, a light L1 emitted from the surface opposed to the second substrate 104 of the light-emitting element 116 may travel toward the second substrate 104, and a light L2 and a light L3 emitted in the oblique direction and transverse direction are reflected at the side surface 140 of the first structure 132 and then change the traveling direction toward the second substrate 104. Therefore, in the pixel 118, the light emitted from the light-emitting element 116 and directly emitted through the second substrate 104 can be the outgoing light in addition to the light emitted toward the first structure 132 side.

Next, in the case where the reflective film 120 having a higher reflectance of light is arranged on the side surface 140, a light L4 and a light L5 emitted toward the reflective film 120 of the light-emitting element 116 are reflected at the reflective film 120, and change their traveling direction. Specifically, as shown in FIG. 3, the light L4 and the light L5 emitted toward the reflective film 120 of the light-emitting element 116 are reflected at the reflective film 120, and then they can change their traveling direction toward the second substrate 104. Of the light L4 and the light L5, light transmitted through the reflective film 120 may be reflected on the side surface 140 of the first structure 132 and changes its traveling direction to the second substrate 104 similar to the light L2 and L3. As described above, since the first structure 132 has the reflective surface, the light emitted from the light-emitting element 116 can change the traveling direction toward the second substrate 104. As a result, in the pixel 118, the light emitted from the light-emitting element 116 and directly emitted through the second substrate 104 can be the outgoing light in addition to the light emitted toward the first structure 132 side.

As the second substrate 104, it is preferable to use a substrate having a higher transmittance of the light emitted from the light-emitting element 116 because the light emitted from the light-emitting element 116 is transmitted. Therefore, for example, a light transmittance substrate such as a polyimide substrate, an acryl substrate, a siloxane substrate, a fluororesin substrate, or a glass substrate can be used as the second substrate 104.

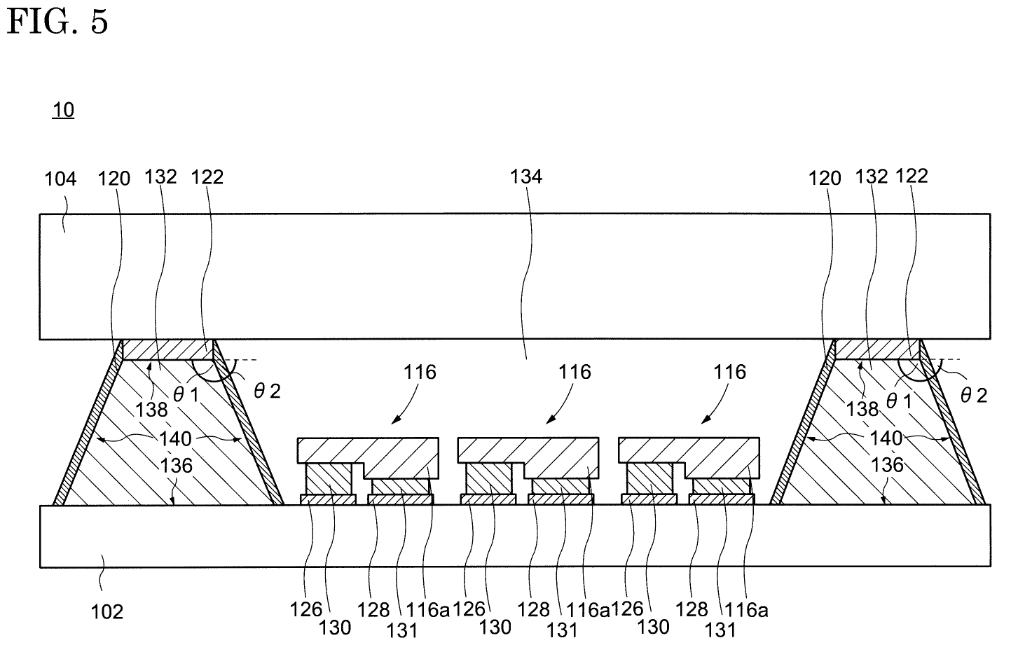

Next, an example in which the plurality of light-emitting elements 116 is stored in one containment portion 134 will be described with reference to FIG. 5.

As shown in FIG. 5, in the case where the plurality of light-emitting elements 116 is arranged in a single containment portion 134, the plurality of light-emitting elements 116 may be sandwiched between the side surface 140 of the first structure 132. In FIG. 5, although the example is shown in which the plurality of light-emitting elements 116 is arranged side by side, the plurality of light-emitting elements 116 may be arranged vertically, and in particular, the arrangement of the light-emitting element 116 is not limited.

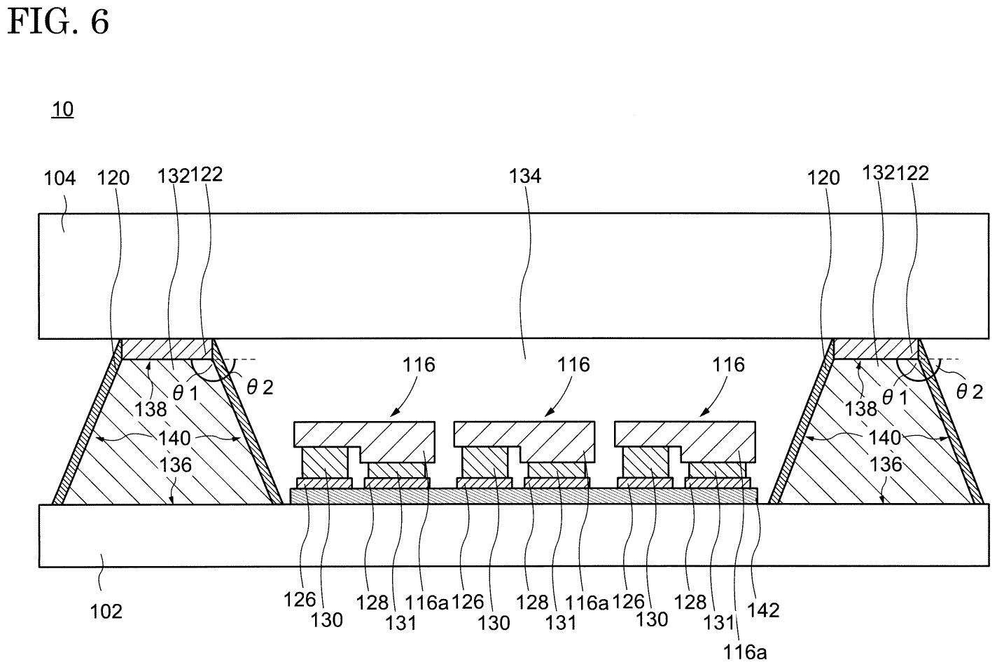

In addition, as shown in FIG. 6, the plurality of light-emitting elements 116 may be arranged on the third substrate 142. The third substrate 142 on which the plurality of light-emitting elements 116 is arranged may be arranged in the first substrate 102 so as to be arranged inside the containment portion 134. In addition, the same substrate as the first substrate 102 may be used for the third substrate 142, and a modular substrate in which a drive circuit of the plurality of light-emitting elements 116 is mounted may be used. Arranging the plurality of light-emitting elements 116 in the third substrate 142 makes it possible to simplify the manufacturing process of the structure arranged in the first substrate 102.

### 3. Modifications

### 3-1. Modification 1

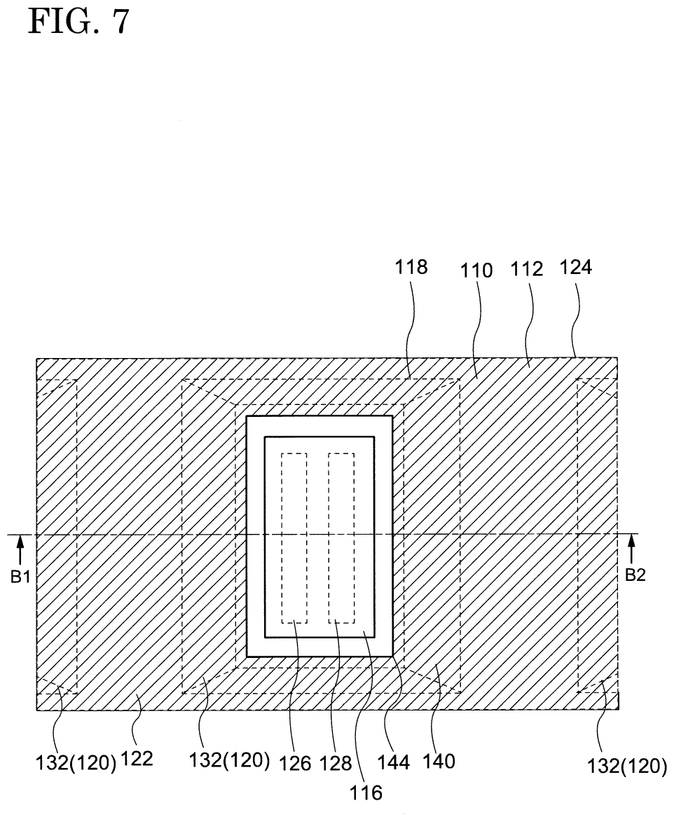

A modification of the display device 10 will be described with reference to FIG. 7. A difference from the display device 10 shown in FIG. 1 to FIG. 3 is that the light-shielding film 122 is larger than the first surface 138 of the first structure 132. Configurations that are the same as or similar to those of the display device 10 shown in FIG. 1 to FIG. 3 may be omitted.

FIG. 7 shows a plan view of the light-emitting element 116 from the second substrate 104. The second substrate 104 is not shown for convenience. As shown in FIG. 7, since the light-shielding film 122 is arranged so as to cover the reflective film 120 (the side surface 140 which is not shown), in a plan view, the opening 144 of the light-shielding film 122 is arranged so as to surround the outer shape of the light-emitting element 116.

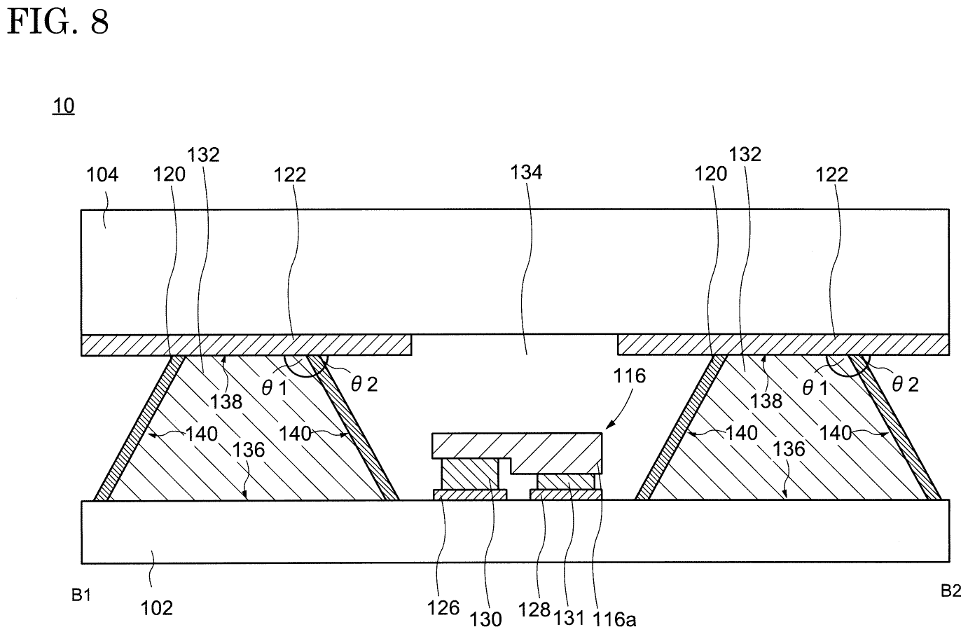

FIG. 8 is a schematic cross-sectional view along a line B1-B2 shown in FIG. 7.

As shown in FIG. 8, in a cross-sectional view, the width of the light-shielding film 122 is larger than the width of the first surface 138 of the first structure 132. In addition, the light-shielding film 122 is arranged to overlap the side surface 140 of the first structure 132. In this case, the light-shielding film 122 is not arranged in the second substrate 104 above the light-emitting element 116. In this case, the direction above the light-emitting element 116 is defined as a direction in which the light of the light-emitting element 116 is emitted toward the second substrate 104.

As shown in FIG. 7 and FIG. 8, the light-shielding film 122 is arranged so as to overlap the reflective film 120 or the side surface 140 in a plan view, so that external light does not enter the reflective film 120 or the side surface 140, and it is possible to prevent the display screen from being mirrored. As a result, the contrast can be improved.

### 3-2. Modification 2

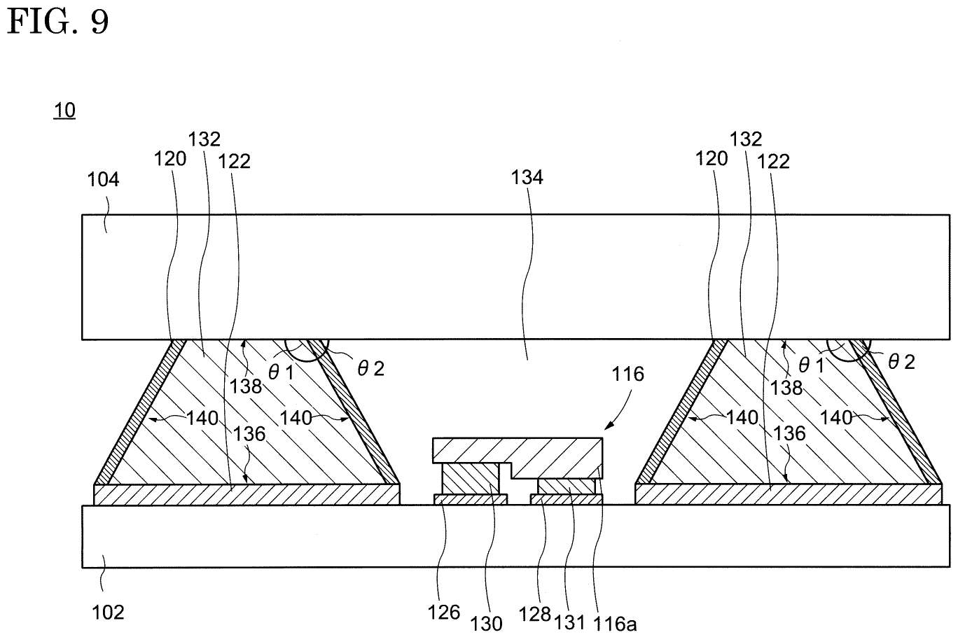

A modification of the display device 10 will be described with reference to FIG. 9. A difference from the display device 10 shown in FIG. 3 is that the light-shielding film 122 is arranged between the first substrate 102 and the first structure 132. Configurations that are the same as or similar to those of the display device 10 shown in FIG. 3 may be omitted.

As shown in FIG. 9, the light-shielding film 122 is arranged between the first structure 132 and the first substrate 102. The light-shielding film 122 is arranged on the second surface 136 of the first structure 132. In a cross-sectional view, the light-shielding film 122 may have the same size as the second surface 136 of the first structure 132. As described above, the light-shielding film 122 is arranged between the first substrate 102 and the first structure 132, so that it is possible to suppress light reflected or scattered by the first substrate 102 without passing through the first structure 132.

### 3-3. Modification 3

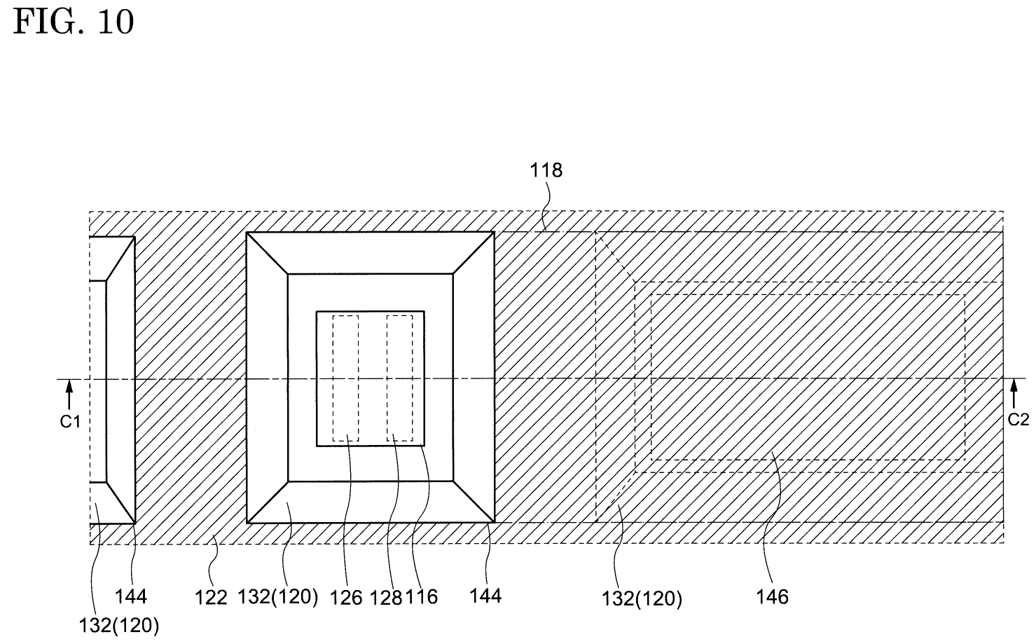

A modification of the display device 10 will be described with reference to FIG. 10. A difference from the display device 10 shown in FIG. 1 to FIG. 3 is that an IC chip 146 is arranged in the pixel 118. Configurations that are the same as or similar to those of the display device 10 shown in FIG. 1 to FIG. 3 may be omitted.

FIG. 10 shows a schematic plan view of the IC chip 146 viewed from the second substrate 104. As shown in FIG. 10, the IC chip 146 is arranged in the opening pattern of the first structure 132, which is adjacent to the light-emitting element 116, so that it is surrounded by the side surface 140 or the reflective film 120 of the 1st structure 132. In this case, the pixel 118 is assumed to be an area including the light-emitting element 116 and the IC chip 146. In FIG. 10, although the example is shown in which one light-emitting element 116 and the IC chip 146 are arranged in the pixel 118, the plurality of light-emitting elements 116 and the IC chip 146 may be arranged in the pixel 118, and for example, two or more sets of the light-emitting element 116 and the IC chip 146 may be arranged in one pixel 118 when a red light-emitting element, a green light-emitting element, and a blue light-emitting element are set as one set.

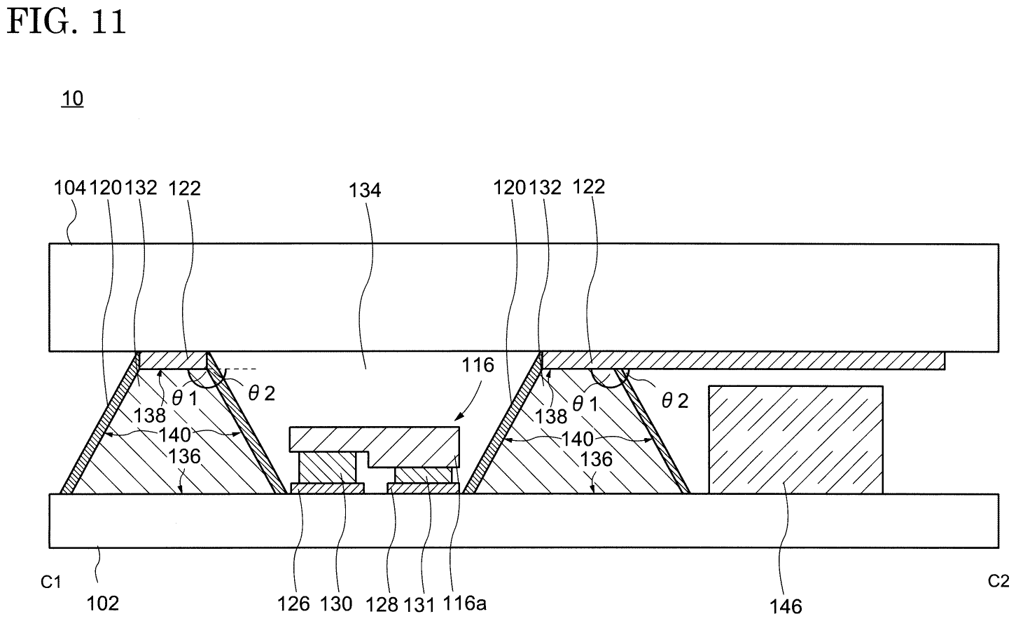

FIG. 11 is a schematic cross-sectional view along a line C1-C2 shown in FIG. 10. As shown in FIG. 11, the IC chip 146 is arranged so as to sandwich the light-emitting element 116 and the first structure 132. The IC chip 146 is electrically connected to the light-emitting element 116 and is arranged in the pixel 118 where the light-emitting element 116 is arranged as described above. The light-shielding film 122 located between the first structure 132 and the second substrate 104 between the first light-emitting element 116 and the IC chip 146 extends on the IC chip 146 and is arranged to overlap the IC chip 146. The IC chip 146 is arranged between the light-shielding film 122 and the first substrate 102 in a cross-sectional view. The IC chip 146 is sandwiched between the side surface 140 of the first structure 132 and the side surface 140 of the adjacent first structure 132, and is arranged between the first substrate 102 and the second substrate 104, and a filling material may be arranged on the IC chip 146 as in the light-emitting element 116.

The IC chip 146 is arranged in the pixel 118 such that the first structure 132 is sandwiched between the light-emitting element 116 and the IC chip 146, and the light-shielding film 122 is arranged so as to cover the IC chip 146, thereby suppressing the emission of the light reflected or scattered by the IC chip 146 to the outside of the display device 10. In addition, since the first structure 132 is located between the IC chip 146 and the light-emitting element 116, the light of the light-emitting element 116 is reflected at the side surface 140 of the first structure 132, and it is possible to suppress the light traveling toward the IC chip 146.

### 3-4. Modification 4

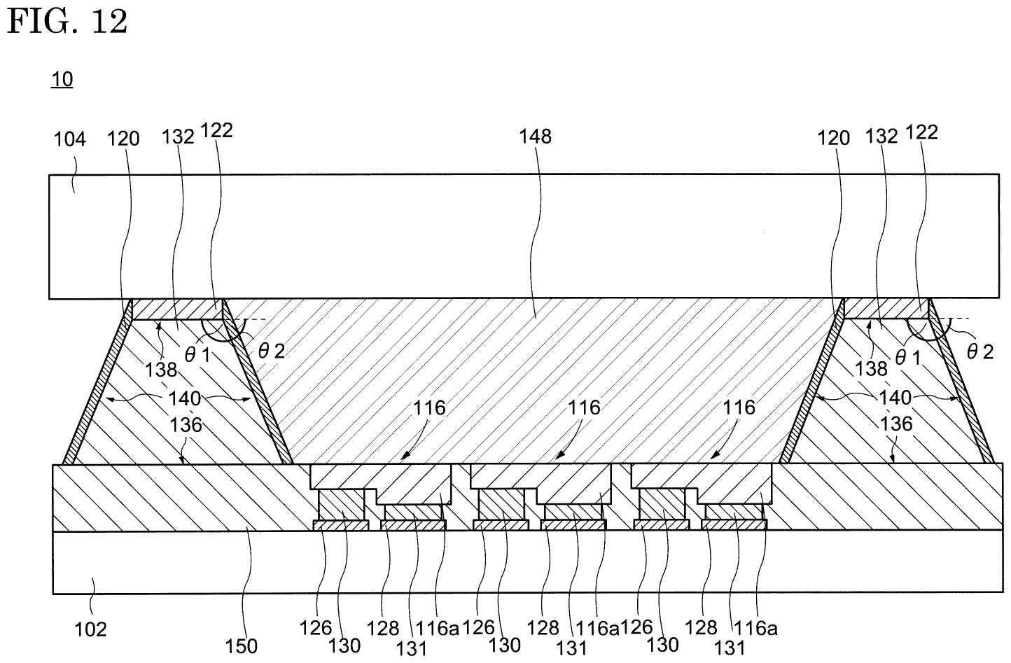

A modification of the display device 10 will be described with reference to FIG. 12. A difference from the display device 10 shown in FIG. 1 to FIG. 3 is that a second structure 148 is arranged between the light-emitting element 116 and the second substrate 104. Configurations that are the same as or similar to those of the display device 10 shown in FIG. 3 may be omitted.

The second structure 148 is arranged on a surface of the second substrate 104 facing the first substrate 102. The second structure 148 is arranged so as to be sandwiched between the side surface 140 of the first structure 132 in a cross-sectional view. In FIG. 12, although the example is shown in which the reflective film 120 is arranged between the second structure 148 and the first structure 132, the reflective film 120 may not be arranged therebetween, and the second structure 148 may be arranged so as to be in contact with the first structure 132. In addition, the second structure 148 is arranged to face the light-emitting element 116. The second structure 148 may be in contact with the light-emitting element 116, and in particular, the second surface 136, which is opposite the first surface 138, which is facing the second substrate 104 of the second structure 148, may be in contact with the upper surface, which is the light-emitting surface of the light-emitting element 116. An adhesive layer may be arranged between the second structure 148 and the light-emitting element 116. In this case, the same material as the material used for the second structure 148, or the same material as the refractive index of the material used for the second structure 148 is used for the adhesive layer.

The second surface 136 of the second structure 148 is larger than the first surface 138. Specifically, as shown in FIG. 12, in a cross-sectional view, the width of the second surface 136 of the second structure is larger than the width of the first surface 138. In addition, the second surface 136 of the second structure 148 may be arranged in the same plane as the second surface 136 of the first structure 132.

A planarization film 150 may be arranged between the second surface 136 of the second structure 148 and the first structure 132 and the first substrate 102. The planarization film 150 is arranged to fill steps of the first conductive layer 126, the second conductive layer 128, and the light-emitting element 116. The planarization film 150 planarizes the steps of the light-emitting element 116 and the like mounted on the first substrate 102. For example, an acrylic resin, a polyimide resin, or the like can be used as a material for the planarization film 150.

An adhesive layer may be arranged between the planarization film 150 and the first structure 132 and between the planarization film 150 and the second structure 148. The same material as the adhesive layer used between the light-emitting element 116 and the second structure 148 can be used for the adhesive layer.

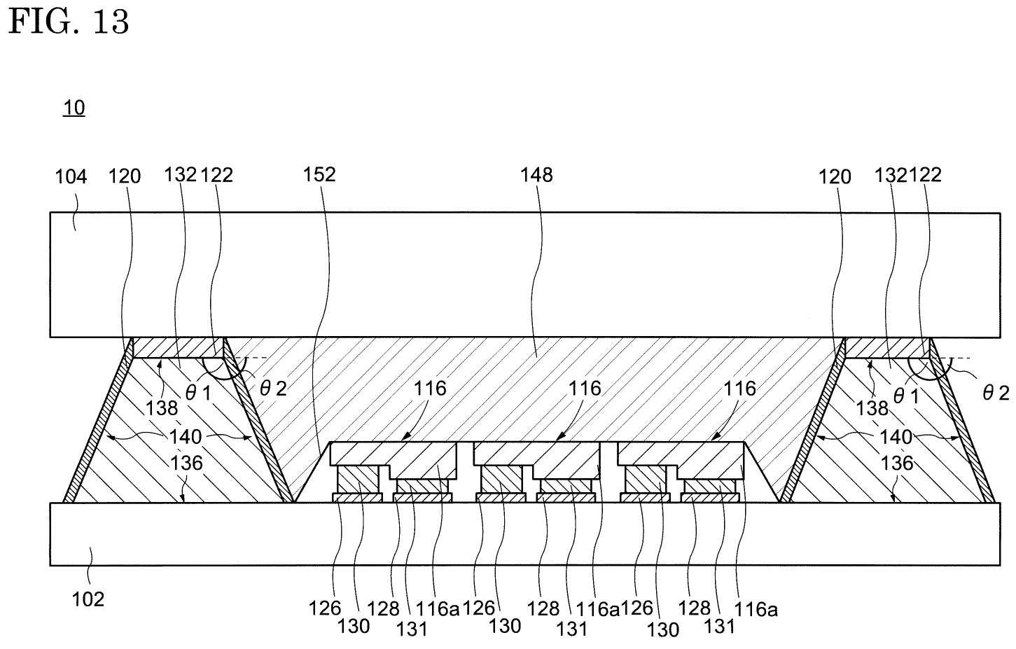

As shown in FIG. 13, if the planarization film 150 is not arranged between the first structure 132 and the second structure 148, a concave portion 152 may be arranged in the second structure 148. Specifically, the concave portion 152 is concave from the first substrate 102 toward the second substrate 104. The concave portion 152 is arranged so as to be sandwiched between the side surface 140 of the first structure 132 in a cross-sectional view. Since the concave portion 152 is located between the second structure 148 and the first substrate 102, the light-emitting element 116 between the second structure 148 and the first substrate 102 may be stored. In addition, the light-emitting element 116 and the second structure can be arranged so that the surface of the second structure 148 facing the first substrate 102 and the light-emitting surface of the light-emitting element 116 are in contact with each other. An adhesive layer having a refractive index that is the same as or similar to the refractive index of the second structure 148 may be arranged between the surface of the second structure 148 facing the first substrate 102 and the light-emitting surface of the light-emitting element 116. Alternatively, a gap may be arranged between the surface of the second structure 148 facing the first substrate 102 and the light-emitting surface of the light-emitting element 116. In addition, the first substrate 102 and the first structure 132 are preferably arranged so as to be in contact with each other. Therefore, a thickness obtained by combining the light-emitting element 116, the first conductive layer 126, and the second conductive layer 128 may be equal to or less than the distance from the surface of the second structure 148 facing the first substrate 102 to the first substrate 102.

As shown in FIG. 13, although the example is shown in which the concave portion 152 of the second structure 148 has a trapezoidal shape in a cross-sectional view, it is not limited to this and maybe a rectangle.

As described above, in the display device 10, the light-emitting element 116 is arranged on the first substrate 102, the first structure 132 is arranged on the second substrate 104 facing the first substrate 102 so as to surround the light-emitting element 116, the light-shielding film is arranged on the side surface 140 of the first structure 132, and the supplementary angle θ2 of the inclination angle θ1 of the side surface 140 is 30 degrees or more and less than 90 degrees, so that the light of the light-emitting element 116 is easily gathered in front of the display device 10, thereby it is possible to provide the display device 10 having a higher front brightness. Further, arranging the light-shielding film 122 on the first surface 138 or the second surface 136 of the first structure 132 in the display device 10 makes it possible to suppress light reflected or scattered by the first substrate 102, so that it is possible to provide a high contrast display device 10.

### SECOND EMBODIMENT

In the present embodiment, a configuration of a display device according to an embodiment of the present invention will be described. One of the differences between the display device 20 of the second embodiment and the display device 20 of the first embodiment is that the inclination angle θ1 of the side surface 140 of the first structure 232 is less than 90 degrees. Descriptions of the same or similar configurations as those of the first embodiment may be omitted.

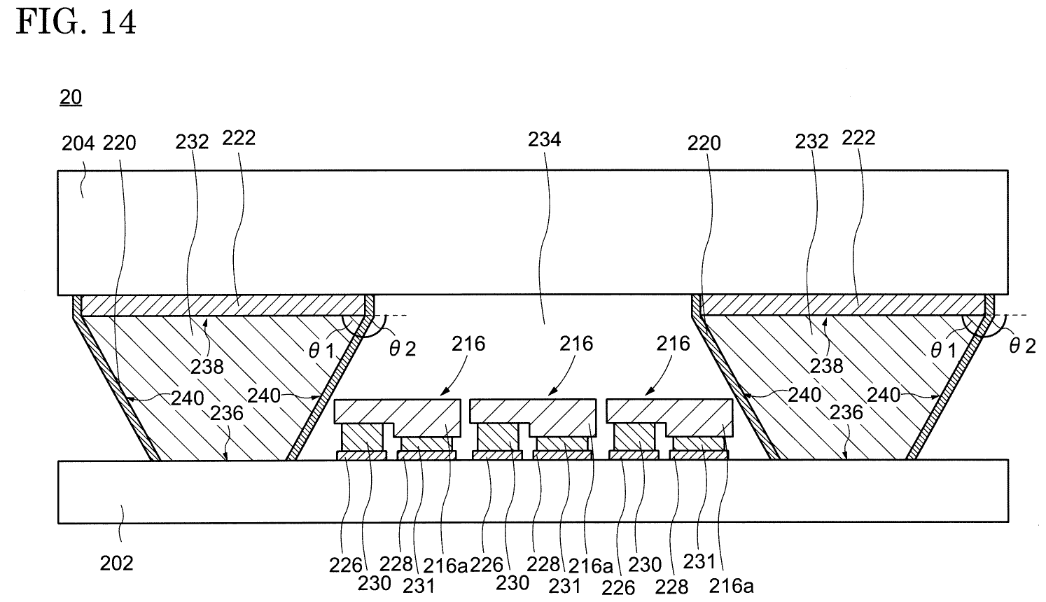

FIG. 14 shows a schematic cross-sectional view of the display device 20. As shown in FIG. 14, the first structure 232 is arranged on the second substrate 204, and the first surface 238 on the second substrate 204 side is larger than the second surface 236 on the first substrate 202 side. In addition, as shown in FIG. 14, in a cross-sectional view, the width of the first surface 238 of the first structure is larger than the width of the second surface 236. Further, the area of the first surface 238 is larger than the area of the second surface 236, so that the side surface 140 is inclined and connected to the first surface 238 and the second surface 236. For example, the inclination angle θ1 of the side surface with respect to the first surface 238 is 30 degrees or more and less than 90 degrees.

As described above, in the display device 20, the inclination angle θ1 of the side surface of the first structure 232 is set to 30 degrees or more and less than 90 degrees, and the light-shielding film 222 is arranged between the first structure 232 and the second substrate 204 to surround light-emitting element 216 with the first structure 232, the traveling direction of the light emitted from light-emitting element 216 can be adjusted, and further, the light reflected or scattered by the first substrate 202 can be suppressed, and it is possible to provide the display device 20 with high front brightness and high contrast.

What is claimed is:

1. A display device comprising:
a first substrate;
a light-emitting element on the first substrate;
a second substrate opposed to the first substrate;
a first protruding structure surrounding the light-emitting element on a surface of the second substrate opposed to the first substrate; and
a light-shielding film overlapping the first protruding structure between the first substrate and the second substrate,
wherein a supplementary angle of an inclination angle of a side surface of the first protruding structure is 30 degrees or more and 90 degrees or less.

2. The display device according to claim 1, further comprising:
a reflective film on the side surface of the first protruding structure.

3. The display device according to claim 1,
wherein the light-shielding film is located between the first protruding structure and the second substrate.

4. The display device according to claim 3,
wherein a surface of the first protruding structure on a side of the second substrate is smaller than the light-shielding film.

5. The display device according to claim 3, further comprising:
an IC chip electrically connected to the light-emitting element between the light-shielding layer and the first substrate,
wherein the light-emitting element and the IC chip are arranged in a pixel, and
the light-shielding film is arranged to overlap the IC chip.

6. The display device according to claim 1,
wherein the light-shielding film is located between the first protruding structure and the first substrate.

7. The display device according to claim 1, further comprising:
an organic layer between the light-emitting element and the second substrate.

8. The display device according to claim 1, further comprising:
a second structure facing the light-emitting element on a surface of the second substrate opposed to the first substrate,
wherein a refractive index of the first protruding structure is greater than refractive indices of the second substrate and the second structure.

9. The display device according to claim 8,
wherein the second structure is concave with respect to the light-emitting element.

10. A display device comprising:
a first substrate;
a light-emitting element on the first substrate;
a second substrate opposed to the first substrate;
a first protruding structure surrounding the light-emitting element on a surface of the second substrate opposed to the first substrate; and
a light-shielding film overlapping the first protruding structure between the first substrate and the second substrate,
wherein an inclination angle of a side surface of the first protruding structure is 30 degrees or more and 90 degrees or less.

11. The display device according to claim 10, further comprising:
a reflective film on the side surface of the first protruding structure.

12. The display device according to claim 10,
wherein the light-shielding film is located between the first protruding structure and the second substrate.

13. The display device according to claim 12,
wherein a surface of the first protruding structure on a side of the second substrate is smaller than the light-shielding film.

14. The display device according to claim 12, further comprising:
an IC chip electrically connected to the light-emitting element between the light-shielding layer and the first substrate,
wherein the light-emitting element and the IC chip are arranged in a pixel, and
the light-shielding film is arranged to overlap the IC chip.

15. The display device according to claim 10,
wherein the light-shielding film is located between the first protruding structure and the first substrate.

16. The display device according to claim 10, further comprising:
an organic layer between the light-emitting element and the second substrate.

17. The display device according to claim 10, further comprising:
a second structure facing the light-emitting element on the surface of the second substrate opposed to the first substrate,
wherein a refractive index of the first protruding structure is greater than refractive indices of the second substrate and the second structure.

18. The display device according to claim 17,
wherein the second structure is concave with respect to the light-emitting element.
